(19) United States
(12) Patent Application Publication
(10) Pub. No.: US 2019/0038070 A1
(43) Pub. Date: Feb. 7, 2019

(54) GRAPHITE POT AND MANUFACTURING METHOD THEREOF

(71) Applicants: FOSHAN SHUNDE MIDEA ELECTRICAL HEATING APPLIANCES MANUFACTURING CO., LIMITED, Foshan City (CN); MIDEA GROUP CO., LTD., Foshan (CN)

(72) Inventors: Dahua CAO, Foshan (CN); Beiyang XIAO, Foshan (CN); Ling YANG, Foshan (CN); Hongwei LI, Foshan (CN); Ning LI, Foshan (CN); Kang LI, Foshan (CN)

(21) Appl. No.: 16/155,676

(22) Filed: Oct. 9, 2018

Related U.S. Application Data
(63) Continuation of application No. PCT/CN2016/104783, filed on Nov. 4, 2016.

(30) Foreign Application Priority Data
Apr. 15, 2016 (CN) 201610239018.6
Apr. 15, 2016 (CN) 201610239894.9

(51) Int. Cl. A47J 36/02; A47J 36/04; C23C 14/00; C23C 14/06

(52) U.S. Cl. CPC A47J 36/025; C23C 14/0635; C23C 14/0036; A47J 36/04

(57) ABSTRACT

The present disclosure provides a graphite pot and a manufacturing method thereof. The graphite pot comprises a pot body made of graphite, the pot body comprising an inner wall and an outer wall, and a hard carbon film or a covalent carbide film attached to the surface of the inner wall. A hard carbon film or a covalent carbide film is attached to the surface of the inner wall of the pot body, and the hardness of the hard carbon film and the hardness of the covalent carbide film are both higher than that of the existing PTFE resin film layer, and the carbon film and the covalent carbide film have superior air permeability. When in use, the far infrared characteristic and the adsorption property of the graphite pot body are fully exerted, which is very environment-friendly and healthy.

### CROSS REFERENCE TO RELATED APPLICATIONS

This application is a continuation application of PCT/CN2016/104783, entitled “GRAPHITE POT AND MANUFACTURING METHOD THEREFOR” filed on Nov. 4, 2016, which claims priority to Chinese Patent Application No. 201610239018.6, filed with the State Intellectual Property Office of the People's Republic of China on Apr. 15, 2016, and entitled “GRAPHITE POT AND MANUFACTURING METHOD THEREFOR”, and Chinese Patent Application No. 201610239894.9, filed with the State Intellectual Property Office of the People's Republic of China on Apr. 15, 2016, and entitled “GRAPHITE POT AND MANUFACTURING METHOD THEREFOR”, all of which are incorporated herein by reference in their entirety.

### TECHNICAL FIELD

The present disclosure relates to the technical field of cooking appliances, and particularly to a graphite pot and a manufacturing method thereof.

### BACKGROUND

Graphite is composed of carbon atoms. Amino acids and nucleotides, the basic units of life, are also obtained by taking elemental carbon as a skeleton. It can be said that if there is no carbon, there is no life. Therefore, although graphite looks black, it is the purest material in the life world, and has good improvement and health care effect on a human body.

1. A graphite product can release far infrared rays after being heated.

Far infrared rays can enhance body functions, to make the human body full of vigor and vitality, and effectively prevent various diseases, for example, activating water molecules and improving the oxygen content in the body, to make people quick-witted and in high spirits; enhancing metabolism and regulating neurohumor; effectively preventing the diseases caused by metabolism disorders, such as diabetes, hyperlipidemia, obesity, gout; improving blood circulation, particularly the microcirculatory system; being capable of preventing the diseases caused by the disorders of the microcirculatory system, such as hypertension, cardiovascular diseases, tumors, arthritis, icy cold limbs and quadriplegia; having the effects of whitening and beautifying, diminishing inflammation and relieving swelling; improving the immunological function of a human body, regulating acid-base equilibrium of blood, reducing alcohol and tobacco, enhancing the liver functions, and other efficacies.

2. A graphite product has good adsorbability.

The porous structure of carbon enables carbon to have good adsorbability, so carbon is often used as an adsorption material for adsorbing moisture, odors, toxic substances, etc. The inventors have done an experiment, i.e., a graphite baking tray used for roasting meat a few days ago looked very clean, but when it was heated by an induction cooker, grease and harmful substances adsorbed during the process of roasting meat could be seen to slowly seep out. However, people do not need to worry about it, as the tray can be cleaned just with a paper napkin.

3. A graphite product has superior thermal conductivity, can transfer heat rapidly, can be heated evenly and can save fuel.

A baking tray, a pot, etc. that are made of graphite can be heated quickly, food cooked by them is evenly heated and is cooked from the inside to the outside, the heating duration is short, and the obtained food has good taste with the original nutrients retained. The inventors have done an experiment, i.e., when a graphite baking tray was used for roasting meat, at the beginning, the induction cooker was switched to the high-heat mode and could be warmed up only in 20-30 seconds, then when food was placed on the induction cooker, the induction cooker only needed to be switched to the low-heat mode, which is beneficial to energy saving.

4. A graphite product has chemical stability and erosion resistance.

Graphite has good chemical stability at normal temperature, and is insusceptible to erosion by any strong acid, strong base and organic solvent. Therefore, a graphite product has little loss even after a long-term use, and it looks new as long as it is wiped clean. The graphite product is environment-friendly, healthy, free of radioactive pollution and resistant to high temperatures.

5. Carbon needs to experience a graphitization process of at least ten days and nights in a high-temperature environment of 2000-3300° C. in order to become graphite. Thus, all the toxic and harmful substances in graphite have already been released, and graphite is stable at least at a temperature of lower than 2000° C. A graphite pot has the above advantages. However, graphite is relatively soft and not wear-resistant, and carbon powder easily falls off graphite in the using process. The general approach to solve this at present is to coat the surface of graphite with a layer of PTFE-containing resin film. However, due to the excellent compactness of such a coating, the far infrared characteristic and the adsorption property of the graphite pot are weakened.

### SUMMARY

The present disclosure provides a graphite pot and a manufacturing method thereof, so as to solve the technical problem that due to the excellent compactness of the coating of a graphite pot, the far infrared characteristic and the adsorption property of the graphite pot are weakened.

In order to solve the above technical problem, an embodiment of the first aspect of the present disclosure provides a graphite pot, comprising a pot body made of graphite, the pot body comprising an inner wall and an outer wall, a hard carbon film being attached to at least the inner wall.

The advantageous effects of the present disclosure are: a hard carbon film is attached to the surface of the inner wall of the pot body, and the hardness of the hard carbon film is higher than that of the existing PTFE resin film layer, which ensures the wear resistance of the graphite pot, and the carbon film itself has superior air permeability, which gives full play to the properties of high thermal conductivity, rapid heat transfer and being heated evenly of the graphite pot body; and in the using process, the far infrared characteristic and the adsorption property of the graphite pot body are fully exerted, which is very environment-friendly and healthy.

Further, a non-stick coating is attached to the surface of the hard carbon film. The advantageous effects of using the above further solution are: the further attachment of a non-stick coating to the surface of the hard carbon film improves the non-adhesive property of the graphite pot, and furthermore, since the hard carbon film is the bottom layer of the non-stick coating, the whole coating of the graphite pot is relatively thin, which will not affect the properties of the graphite pot.

Further, a non-stick coating or a hard carbon film is attached to the outer wall. The advantageous effects of using the above further solution are: the attachment of a non-stick coating to the surface of the outer wall improves the wear resistance of the outer wall of the graphite pot; and the attachment of a hard carbon film to the surface of the outer wall ensures the wear resistance of the graphite pot itself without affecting the properties of the graphite pot.

Furthermore, the thickness of the carbon film ranges from 1.0 μm to 50 μm.

The advantageous effects of using the above further solution are: the carbon film having a thickness ranging from 1.0 μm to 50 μm ensures the exertion of the favorable properties of the graphite pot body, while ensuring the wear resistance of the graphite pot.

Furthermore, the thickness of the carbon film ranges from 10 μm to 30 μm.

The advantageous effects of using the above further solution are: the carbon film having a thickness ranging from 10 μm to 30 μm enables the graphite pot to have the best performance.

An embodiment of the second aspect of the present disclosure provides a graphite pot, comprising a pot body made of graphite, the pot body comprising an inner wall and an outer wall, a covalent carbide film being attached to the inner wall.

The advantageous effects of the present disclosure are: as a covalent carbide film is attached to the surface of the pot body, and the hardness of the covalent carbide film is far higher than that of the existing PTFE resin film layer, only after tens of thousands of times of use, can the film layer be worn through, which ensures the wear resistance of the graphite pot, and prolongs the service life of the graphite pot; moreover, the covalent carbide film itself has superior air permeability, which gives full play to the properties of high thermal conductivity, rapid heat transfer and being heated evenly of the graphite pot body.

Further, a non-stick coating is attached to the surface of the covalent carbide film.

The advantageous effects of using the above further solution are: the further attachment of a non-stick coating to the surface of the covalent carbide film improves the non-adhesive property of the graphite pot, and furthermore, since the covalent carbide film is the bottom layer of the non-stick coating, the whole coating of the graphite pot is relatively thin, which will not affect the properties of the graphite pot.

Further, a non-stick coating or a covalent carbide film is attached to the outer wall. The advantageous effects of using the above further solution are: the attachment of a non-stick coating to the surface of the outer wall improves the wear resistance of the outer wall of the graphite pot; and the attachment of a covalent carbide film to the surface of the outer wall ensures the wear resistance of the graphite pot itself without affecting the properties of the graphite pot.

Furthermore, the thickness of the covalent carbide film ranges from 1.0 μm to 5.0 μm.

The advantageous effects of using the above further solution are: the covalent carbide film having a thickness ranging from 1.0 μm to 5.0 μm ensures the exertion of the favorable properties of the graphite pot body, while ensuring the wear resistance of the graphite pot.

Furthermore, the thickness of the covalent carbide film ranges from 2.5 μm to 3.5 μm.

The advantageous effects of using the above further solution are: the SiC film having a thickness ranging from 2.5 μm to 3.5 μm enables the graphite pot to have the best wear resistance and the best performance.

Further, the covalent carbide film is a silicon carbide film, a boron carbide film or a titanium carbide film.

The advantageous effects of using the above further solution are: the covalent carbide films such as a silicon carbide film, a boron carbide film or a titanium carbide film have the characteristics of high hardness, being resistant to corrosion and good heat stability, and also have high chemical stability.

An embodiment of the third aspect of the present disclosure provides a method for manufacturing a graphite pot, comprising the steps of: molding graphite into a pot body; and subjecting the molded pot body to a coating treatment via chemical vapor deposition or to a coating treatment via physical vapor deposition to form a hard carbon film on a surface of the pot body.

The advantageous effects of the manufacturing method of the present disclosure are: forming a hard carbon film by a coating treatment via chemical vapor deposition or by a coating treatment via physical vapor deposition ensures superior attachment of the hard carbon film to the pot body.

Further, the specific operations of the coating treatment via chemical vapor deposition are as follows: placing the baked pot body into a coating chamber, and closing and vacuumizing the coating chamber; and controlling an air pressure P₁ in the coating chamber, a recovery pressure P₂, glow bar power P₃, an argon flow rate Q₁, a hydrogen flow rate Q₂ and a methane flow rate Q₃, base material temperature T₁ of the pot body and deposition time t₁, and performing coating of the pot body via chemical vapor deposition.

The advantageous effects of using the above further solution are: by controlling the air pressure P₁ in the coating chamber, the recovery pressure P₂, the glow bar power P₃, the argon flow rate Q₁, the hydrogen (H₂) flow rate Q₂ and the methane (CH₄) flow rate Q₃, the base material temperature T₁ of the pot body and the deposition time t₁, it is ensured that the quality and the thickness of the carbon film on the surface of the graphite pot body satisfy the preset requirements.

Further, the air pressure P₁, the recovery pressure P₂, the glow bar power P₃, the argon flow rate Q₁, the hydrogen flow rate Q₂, the methane flow rate Q₃, the base material temperature T₁ of the pot body and the deposition time t₁ satisfy the following relations: P₁ ranges from 0.5 kpa to 7 kpa, P₂ ranges from 50 kpa to 150 kpa, P₃ ranges from 2 kw to 20 kw, Q₁ ranges from 1 SLM to 10 SLM, Q₂ ranges from 0.5 SLM to 4.5 SLM, Q₃ ranges from 0.02 SLM to 0.6 SLM, T₁ ranges from 850° C. to 930° C., and t₁ ranges from 1 hour to 12 hours.

The advantageous effects of using the above further solution are: by controlling the above parameters, it is possible to control the coating thickness of the carbon film on the graphite pot body to be between 10 μm and 50 μm.

Further, the specific operations of the coating treatment via physical vapor deposition are as follows:

placing the baked pot body into a coating chamber, and closing and vacuumizing the coating chamber; and

controlling a background pressure P₄ in the coating chamber, a film-forming pressure P₅, a sputtering power P₆, a bias voltage Vbias, an argon flow rate Q₄, a methane or acetylene flow rate Q₅, base material temperature T₂ of the pot body and deposition time t₂, and performing coating of the pot body via physical vapor deposition.

The advantageous effects of using the above further solution are: by controlling the background pressure P₄ in the coating chamber, the film-forming pressure P₅, the sputtering power P₆, the bias voltage Vbias, the argon (Ar) flow rate Q₄, the methane (CH₄) or acetylene (C₂H₂) flow rate Q₅, the base material temperature T₂ of the pot body and the deposition time t₂, it is ensured that the quality and the thickness of the carbon film on the surface of the graphite pot body satisfy the preset requirements.

Further, the background pressure P₄, the film-forming pressure P₅, the sputtering power P₆, the bias voltage Vbias, the argon flow rate Q₄, and the methane or acetylene flow rate Q₅, the base material temperature T₂ of the pot body and the deposition time t₂ satisfy the following relations: P₄ ranges from 0.5×10⁻² Pa to 0.5×10⁻³ Pa, P₅ ranges from 2.0×10⁻² Pa to 8.0×10⁻¹ Pa, P₆ ranges from 10 kw to 20 kw, Vbias ranges from 100V to 300V, Q₄ ranges from 0.2 SLM to 0.7 SLM, Q₅ ranges from 0.10 SLM to 2.0 SLM, T₂ ranges from 130° C. to 200° C., and t₂ ranges from 3 hours to 5 hours.

The advantageous effects of using the above further solution are: by controlling the above parameters, it is possible to control the coating thickness of the carbon film on the graphite pot body to be between 1.0 μm and 10 μm.

An embodiment of the fourth aspect of the present disclosure provides a method for manufacturing a graphite pot, comprising the steps of: molding graphite into a pot body; and subjecting the molded pot body to a coating treatment via physical vapor deposition to form a covalent carbide film on a surface of the pot body.

The advantageous effects of the manufacturing method of the present disclosure are: forming a covalent carbide film on the pot body by the treatment of coating a covalent carbide film ensures superior attachment of the covalent carbide film to the pot body; moreover, the covalent carbide film also has relatively high hardness.

Furthermore, the coating treatment via physical vapor deposition is sputtering.

The advantageous effects of using the above further solution are: the covalent carbide film after the sputtering treatment has the advantages of strong adhesive force, high throwing power, wide matching between the coated base materials and the coating materials, etc.

Further, the specific operations of the sputtering are as follows:

placing the baked pot body into a coating chamber, and

closing and vacuumizing the coating chamber; and controlling a deposition pressure P₁ in the coating chamber, a sputtering target material, a sputtering power P₂, an argon flow rate Q₁, and an acetylene flow rate Q₂, base material temperature T₁ and deposition time t₁, and performing sputtering of the pot body.

The advantageous effects of using the above further solution are: by controlling the deposition pressure P₁ in the coating chamber, the sputtering target material, the sputtering power P₂, the argon flow rate Q₁, the acetylene flow rate Q₂, the base material temperature T₁ and the deposition time t₁, it is ensured that the quality and the thickness of the covalent carbide film on the surface of the graphite pot body satisfy the preset requirements.

Further, the deposition pressure P₁, the sputtering target material, the sputtering power P₂, the argon flow rate Q₁, the acetylene flow rate Q₂, the base material temperature T₁ and the deposition time t₁ satisfy the following relations:

P₁ ranges from 0.5×10⁻¹ Pa to 5.0×10⁻¹ Pa, the sputtering target material is silicon, boron or titanium, P₂ ranges from 5 kw to 20 kw, Q₁ ranges from 0.05 SLM to 3.0 SLM, Q₂ ranges from 0.04 SLM to 0.10 SLM, T₁ ranges from 110° C. to 130° C., and t₁ ranges from 1.5 hours to 4 hours.

The advantageous effects of using the above further solution are: by controlling the above parameters, it is possible to control the coating thickness of the covalent carbide film on the graphite pot body to be between 1.0 μm and 5.0 μm.

### BRIEF DESCRIPTION OF DRAWINGS

FIG. 1 is a structural diagram of embodiment 1 of a graphite pot of the present disclosure;

FIG. 2 is a structural diagram of embodiment 2 of the graphite pot of the present disclosure;

FIG. 3 is a structural diagram of embodiment 3 of the graphite pot of the present disclosure;

FIG. 4 is a structural diagram of embodiment 4 of the graphite pot of the present disclosure;

FIG. 5 is a structural diagram of embodiment 5 of the graphite pot of the present disclosure;

FIG. 6 is a structural diagram of embodiment 6 of the graphite pot of the present disclosure;

FIG. 7 is a flow chart of a method for manufacturing a graphite pot of the present disclosure; and

FIG. 8 is another flow chart of the method for manufacturing a graphite pot of the present disclosure.

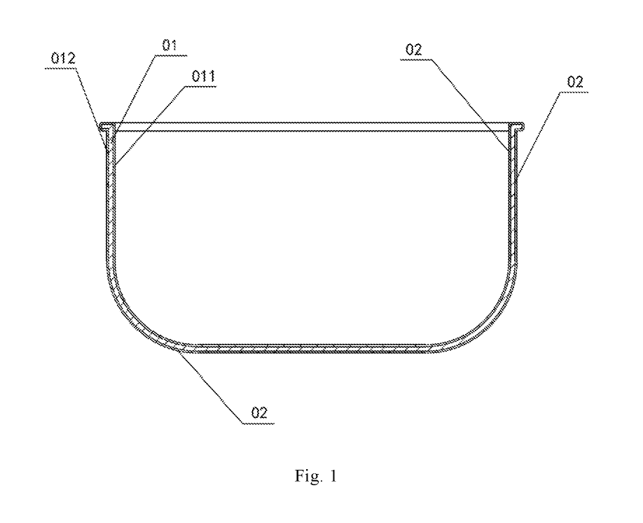

In FIGS. 1-6, the corresponding relation between the reference signs and the components is:

01: pot body, 011: inner wall, 012: outer wall, 02: hard carbon film, 03: non-stick coating, and 04: covalent carbide film.

### DETAILED DESCRIPTION OF EMBODIMENTS

Below, the present disclosure is further described in connection with embodiments with reference to the figures.

The structural diagram of embodiment 1 of a graphite pot of the present disclosure is shown in FIG. 1, which comprises a pot body 01 made of graphite, the pot body 01 comprising an inner wall 011 and an outer wall 012, a hard carbon film 02 attached to the surface of the inner wall 011 and the surface of the outer wall 012, respectively; and the thickness of the hard carbon film 02 being 20 μm.

A hard carbon film is attached to the surface of the inner wall of the pot body, and the hardness of the hard carbon film is higher than that of the existing Polytetrafluoroethylene (PTFE) resin film layer, which ensures the wear resistance of the graphite pot, and the carbon film itself has superior air permeability, which gives full play to the properties of high thermal conductivity, rapid heat transfer and being heated evenly of the graphite pot body; in the using process, the far infrared characteristic and the adsorption property of the graphite pot body are fully exerted, which is very environment-friendly and healthy; and the carbon film having a thickness of 20 μm enables the graphite pot to have the best performance.

In a particular embodiment, the thickness of the carbon film may be set to any other value between 1.0 and 50 μm.

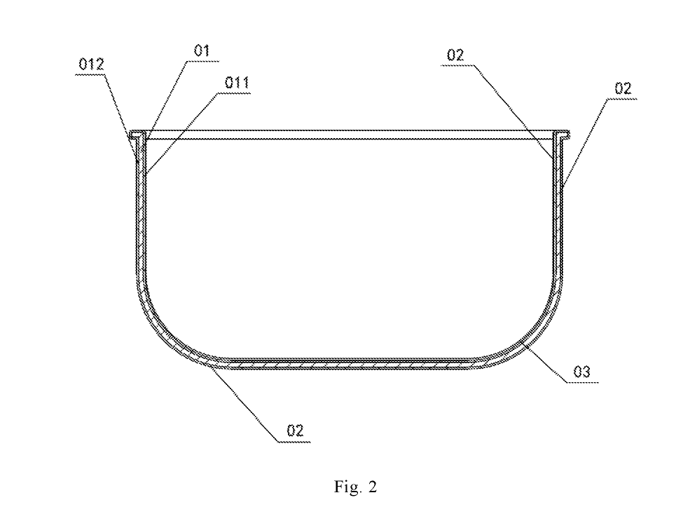

The structural diagram of embodiment 2 of the graphite pot of the present disclosure is shown in FIG. 2, and embodiment 2 is distinguished from embodiment 1 in that a non-stick coating 03 is attached to the surface of the hard carbon film 02.

Further attachment of a non-stick coating to the surface of the hard carbon film improves the non-adhesive property of the graphite pot. Furthermore, since the hard carbon film is the bottom layer of the non-stick coating, the whole coating of the graphite pot is relatively thin, which does not affect the properties of the graphite pot.

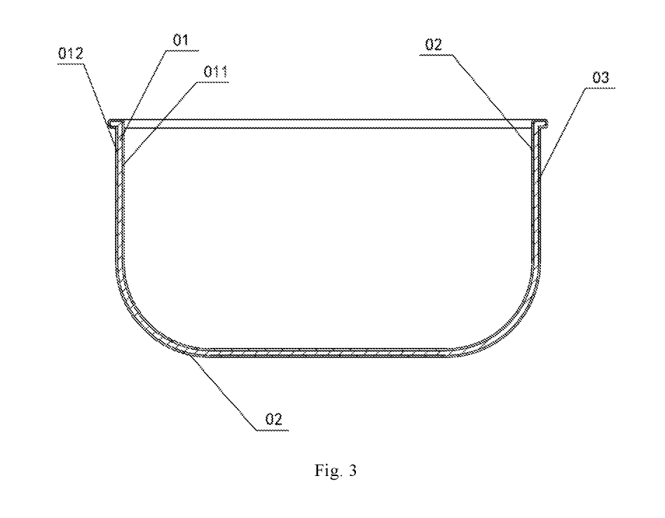

The structural diagram of embodiment 3 of the graphite pot of the present disclosure is shown in FIG. 3, and embodiment 3 is distinguished from embodiment 1 in that a non-stick coating 03 is attached to the surface of the outer wall 012.

The attachment of a non-stick coating to the surface of the outer wall improves the wear resistance of the outer wall of the graphite pot.

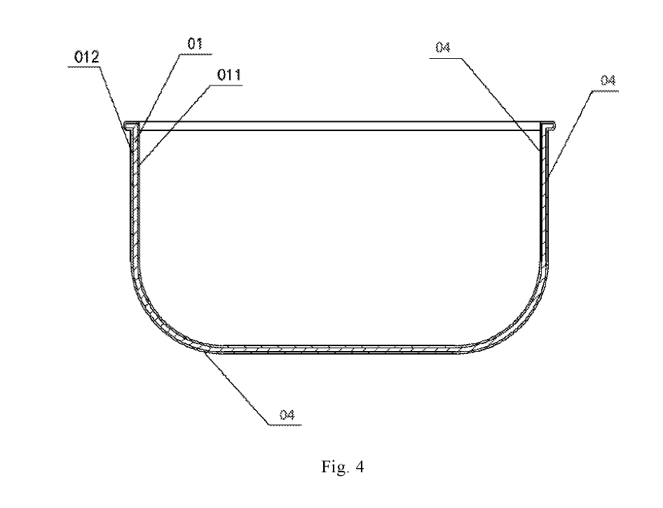

The structural diagram of embodiment 4 of the graphite pot of the present disclosure is shown in FIG. 4, which comprises a pot body 01 made of graphite, the pot body 01 comprising an inner wall 011 and an outer wall 012, a covalent carbide film 04 attached to the surface of the inner wall 011 and the surface of the outer wall 012, respectively, wherein the covalent carbide film 04 is a silicon carbide film, and the thickness of the silicon carbide film is 3.0 μm.

A covalent carbide film, i.e., a silicon carbide film, is attached to the surface of the inner wall. Because the hardness of the silicon carbide film is far higher than that of the existing PTFE resin film layer, the film layer may be worn through only after tens of thousands of times of use, which ensures the wear resistance of the graphite pot and prolongs the service life of the graphite pot. Moreover, the silicon carbide film itself has superior air permeability, which ensures the properties of high thermal conductivity, rapid heat transfer and being heated evenly of the graphite pot body; and the silicon carbide film having a thickness of 3.0 μm enables the graphite pot to have the best performance. The attachment of a covalent carbide film to the surface of the outer wall ensures the wear resistance of the graphite pot itself without affecting the properties of the graphite pot.

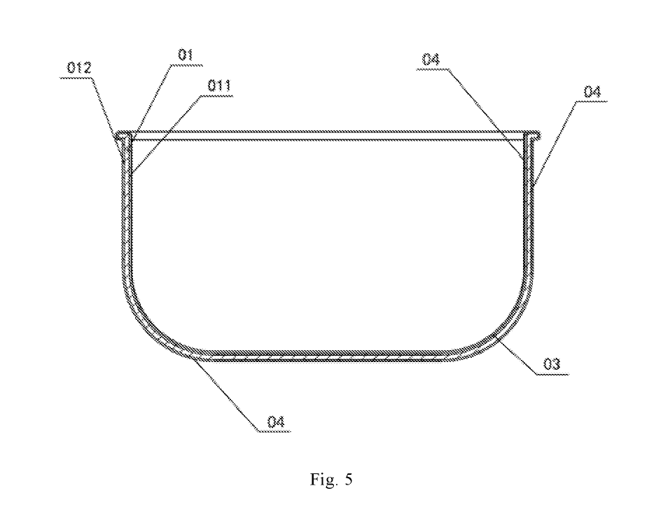

The structural diagram of embodiment 5 of the graphite pot of the present disclosure is shown in FIG. 5, and embodiment 5 is distinguished from embodiment 4 in that a non-stick coating 03 is attached to the surface of the covalent carbide film 04.

Further attachment of a non-stick coating to the surface of the covalent carbide film improves the non-adhesive property of the graphite pot. Furthermore, since the covalent carbide film is the bottom layer of the non-stick coating, the whole coating of the graphite pot is relatively thin, which does not affect the performance of the graphite pot.

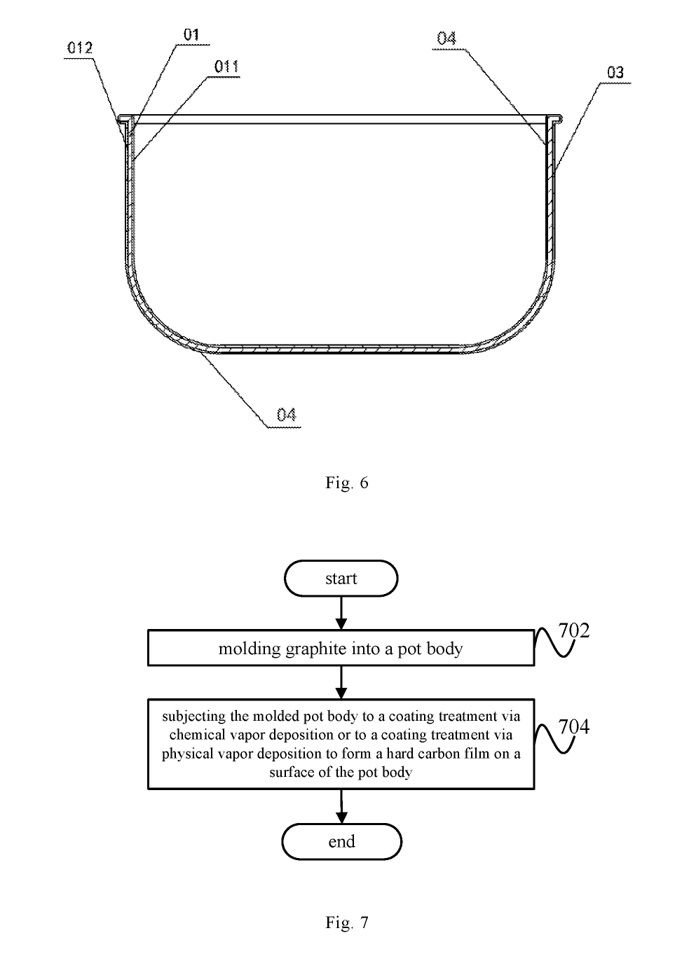

The structural diagram of embodiment 6 of the graphite pot of the present disclosure is shown in FIG. 6, and embodiment 6 is distinguished from embodiment 4 in that a non-stick coating 03 is attached to the surface of the outer wall 012.

The attachment of a non-stick coating to the surface of the outer wall improves the wear resistance of the outer wall of the graphite pot

In a particular embodiment, the thickness of the covalent carbide film may be set to any other value between 1.0 and 5.0 μm.

In a particular embodiment, the covalent carbide film 04 is a silicon carbide film, a boron carbide film or a titanium carbide film, or any other covalent carbide film.

A flow chart of a method for manufacturing a graphite pot of the present disclosure is shown in FIG. 7, which method comprises the steps of:

step 702, molding graphite into a pot body,

wherein the specific operations of step 702 are as follows:
forming graphite into a pot body using computer numerical control (CNC) milling, after compression-molding of graphite;
placing the pot body in an ultrasonic cleaning container for ultrasonic cleaning, wherein the conditions of the ultrasonic cleaning are that:
   the cleaning temperature is 50° C.-60° C., the cleaning time is 5 min-10 min, and the power of the ultrasonic cleaning equipment is selected according to the actual product conditions to ensure that the output power density of the ultrasonic cleaning machine is mostly selected to be 0.3-0.6 W/cm²;
   placing the cleaned pot body in an oven for baking, wherein the baking conditions are:
      the baking temperature is 110° C.-120° C., and the baking time is 15 min-30 min;
      step 704, subjecting the molded pot body to a coating treatment via chemical vapor deposition or to a coating treatment via physical vapor deposition to form a hard carbon film on a surface of the pot body.

Forming a hard carbon film by a coating treatment via chemical vapor deposition or by a coating treatment via physical vapor deposition ensures superior attachment of the hard carbon film to the pot body.

In a specific embodiment, after step 704, the method can further comprise the step of subjecting the pot body, after the treatment of carbon film coating, to the treatment of cleaning. Subjecting the pot body, after the treatment of carbon film coating, to the treatment of cleaning ensures the cleanliness of the surface of the graphite pot, and ensures that the graphite pot can be directly used.

The specific operations of the coating treatment via chemical vapor deposition in step 704 are:

placing the baked pot body into a coating chamber, and closing and vacuumizing the coating chamber; and

controlling an air pressure P₁ in the coating chamber, a recovery pressure P₂, a glow bar power P₃, an argon flow rate Q₁, a hydrogen flow rate Q₂, a methane flow rate Q₃, base material temperature T₁ of the pot body and deposition time t₁, and performing coating of the pot body via chemical vapor deposition. The control ranges of the parameters are shown below in table 1.

TABLE 1
Parameter Control Table of Coating
Via Chemical Vapor Deposition

| | | | gas flow rate (SLM) | | | | |
|---|---|---|---|---|---|---|---|
| P₁(KPa) | P₂(KPa) | P (kw) | Q₁ | Q₂ | Q₃ | T₁ (° C.) | t₁(h) |
| 0.5-7 | 50-150 | 2-20 | 1-10 | 0.5-4.5 | 0.02-0.6 | 850-930 | 1-12 |

In a specific embodiment, the air pressure P₁ in the coating chamber, the recovery pressure P₂, the glow bar power P₃, the argon flow rate Q₁, the hydrogen flow rate Q₂, the methane flow rate Q₃, the base material temperature T₁ of the pot body and the deposition time t₁, and the coating thickness of the carbon film are shown below in table 2.

TABLE 2
Parameters and Coating Thickness of
Coating Via Chemical Vapor Deposition

| | | | gas flow rate | | | | | thickness of |
|---|---|---|---|---|---|---|---|---|
| P₁ | P₂ | P₃ | (SLM) | | | T₁ | t₁ | carbon film |
| (KPa) | (KPa) | (kw) | Q₁ | Q₂ | Q₃ | (° C.) | (h) | (μm) |
| 1 | 60 | 10 | 3 | 1.5 | 0.05 | 870 | 3 | 10 |
| 3 | 80 | 12 | 4 | 2.0 | 0.15 | 890 | 5 | 15 |
| 5 | 100 | 14 | 5 | 2.5 | 0.30 | 910 | 7 | 25 |
| 7 | 120 | 16 | 7 | 3.0 | 0.45 | 930 | 9 | 35 |

The deposition film-forming device of chemical vapor deposition is relatively simple, and allows for easy control of the density of the film layer and the purity of the film layer, which ensures the quality of the carbon film. Moreover, the thickness of the carbon film can be controlled to be 10 μm-50 μm.

The specific operations of the coating treatment via physical vapor deposition are as follows: placing the baked pot body into a coating chamber, and closing and vacuumizing the coating chamber; controlling a background pressure P₄ in the coating chamber, a film-forming pressure P₅, a sputtering power P₆, a bias voltage Vbias, an argon flow rate Q₄, a methane or acetylene flow rate Q₅, base material temperature T₂ of the pot body and deposition time t₂, and performing coating treatment on the pot body via physical vapor deposition. The control ranges of the parameters are shown below in table 3.

TABLE 3
Parameter Control Table of Coating Via Physical Vapor Deposition

| | | | bias | gas flow rate | | | |
|---|---|---|---|---|---|---|---|
| P₄ | P₅ | P₆ | voltage | (SLM) | | T₂ | t₂ |
| (Pa) | (Pa) | (kw) | Vbias (V) | Q₄ | Q₅ | (° C.) | (h) |
| 0.5 × 10⁻²- | 2.0 × 10⁻²- | 10- | 100- | 0.2- | 0.10- | 130- | 3- |
| 0.05 × 10⁻² | 8.0 × 10⁻¹ | 20 | 300 | 0.7 | 2.0 | 200 | 5 |

In a specific embodiment, the background pressure P₄, the film-forming pressure P₅, the sputtering power P₆, the bias voltage Vbias, the argon (Ar) flow rate Q₄, the methane or C₂H₂ flow rate Q₅, the base material temperature T₂ and the deposition time t₂, and the coating thickness of the carbon film are shown below in table 4.

TABLE 4
Parameters and Coating Thickness of
Coating Via Physical Vapor Deposition

| | | | bias | gas flow rate | | | | thickness of |
|---|---|---|---|---|---|---|---|---|
| P₄ | P₅ | P₆ | voltage | (SLM) | | T₂ | t₂ | carbon film |
| (Pa) | (Pa) | (kw) | Vbias (V) | Q₄ | Q₅ | (° C.) | (h) | (μm) |
| 1.0 × | 3.0 × | 12 | 150 | 0.3 | 0.12 | 150 | 2 | 1.0 |
| 10⁻² | 10⁻¹ | | | | | | | |
| 5.0 × | 4.0 × | 15 | 200 | 0.4 | 0.15 | 165 | 3 | 3.0 |
| 10⁻³ | 10⁻¹ | | | | | | | |
| 1.0 × | 6.0 × | 18 | 250 | 0.5 | 0.18 | 180 | 4 | 5.0 |
| 10⁻³ | 10⁻¹ | | | | | | | |

For the physical vapor deposition, it is free of pollution and material-saving, the film formed thereby is uniform and compact and has a strong ability to bond with a base, and self-lubrication of the surface of the carbon film is improved; moreover, the thickness of the carbon film can be controlled between 1.0 μm and 10 μm.

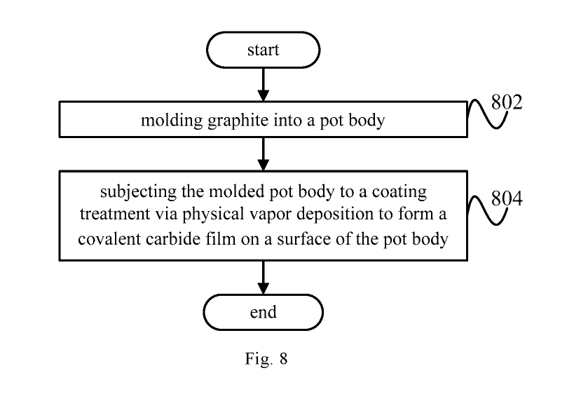

Another flow chart of the method for manufacturing a graphite pot of the present disclosure is shown in FIG. 8, which method comprises the steps of:

step 802, molding graphite into a pot body,

wherein the specific operations of step 802 are as follows:
forming graphite into a pot body using CNC milling, after compression-molding of graphite;
placing the pot body in an ultrasonic cleaning container for ultrasonic cleaning, wherein the conditions of the ultrasonic cleaning are:
   the cleaning temperature is 50° C.-60° C., the cleaning time is 5 min-10 min, and the power of the ultrasonic cleaning equipment is selected according to the actual product conditions to ensure that the output power density of the ultrasonic cleaning machine is mostly selected to be 0.3-0.6 W/cm²;
   placing the cleaned pot body in an oven for baking, wherein the baking conditions are:
      the baking temperature is 110° C.-120° C., and the baking time is 15 min-30 min;
      step 804, subjecting the molded pot body to a coating treatment via physical vapor deposition to form a covalent carbide film on a surface of the pot body.

Forming a covalent carbide film on the pot body by the treatment of coating a covalent carbide film ensures superior attachment of the covalent carbide film to the pot body; moreover, the covalent carbide film also has relatively high hardness.

In a specific embodiment, after step 804, the method further comprises a cleaning step, i.e., subjecting the pot body, after the treatment of covalent carbide film coating, to the treatment of cleaning. Subjecting the pot body, after the treatment of covalent carbide film coating, to the treatment of cleaning ensures the cleanliness of the surface of the graphite pot, and ensures that the graphite pot can be directly used.

In a specific embodiment, the coating treatment via physical vapor deposition is sputtering.

The specific operations of the sputtering are as follows:

placing the baked pot body into a coating chamber, and closing and vacuumizing the coating chamber; and

controlling a deposition pressure P₁ in the coating chamber, a sputtering target material, a sputtering power P₂, an argon flow rate Q₁, an acetylene flow rate Q₂, base material temperature T₁ and deposition time t₁, and performing sputtering of the pot body. The parameter control of the sputtering method is shown below in table 5.

TABLE 5
Parameter Control Table of Sputtering

| P₁ | target | P₂ | gas flow rate (SLM) | | T₁ | t₁ |
|---|---|---|---|---|---|---|
| (Pa) | material | (kw) | Q₁ | Q₂ | (° C.) | (h) |
| 0.5 × 10⁻¹- | Si | 5-20 | 0.05-3.0 | 0.04-1.0 | 110-130 | 1.5-4 |
| 5.0 × 10⁻¹ | | | | | | |

In a specific embodiment, the deposition pressure P₁, the sputtering target material, the sputtering power P₂, the argon (Ar) flow rate Q₁, the acetylene (C₂H₂) flow rate Q₂, the base material temperature T₁ and the deposition time t₁, and the coating thickness and the wear resistance of the SiC film are shown below in table 6.

TABLE 6
Parameter Control, Coating Thickness and Wear Resistance of Sputtering

| | | | | | | | | | wear |
|---|---|---|---|---|---|---|---|---|---|
| | | | | | | | Thickness | | resistance |
| P₁ | target | P₂ | gas flow rate (SLM) | | T₁ | t₁ | of Si film | hardness | (ten thousand |
| (Pa) | material | (kw) | Q₁ | Q₂ | (° C.) | (h) | (μm) | (Hv) | times) |
| 1 × 10⁻¹ | Si | 10 | 0.1 | 0.05 | 120 | 2-3 | 10 | 11 | 1 |
| 2 × 10⁻¹ | | 12 | 0.15 | 0.06 | 120 | 2-3 | 15 | 16 | 1 |
| 3 × 10⁻¹ | | 14 | 0.2 | 0.07 | 120 | 2.5-3.5 | 25 | 26 | 1.2 |
| 4 × 10⁻¹ | | 16 | 0.25 | 0.08 | 120 | 3.0-3.5 | 35 | 36 | 1.3 |

The SiC film treated by sputtering has the advantages of strong adhesive force, high throwing power, wide matching between the coated base materials and the coating materials, etc.; moreover, the thickness of the SiC film can be controlled to be 1.0 μm-5.0 μm.

In the description of the present disclosure, it is to be understood that the orientation or position relation denoted by the terms such as “center”, “length”, “width”, “upper”, “lower”, “vertical”, “horizontal”, “top”, “bottom” and “inner” is based on the orientation or position relation indicated by the figures, which only serves to facilitate describing the present disclosure and simplify the description, rather than indicating or suggesting that the device or element referred to must have a particular orientation, and is constructed and operated in a particular orientation, and therefore cannot be construed as a limitation on the present disclosure.

In the present disclosure, unless otherwise explicitly specified and defined, the terms such as “install”, “link”, “connect” and “fix” shall be understood in broad sense, which may, for example, refer to fixed connection, detachable connection or integral connection; may refer to direct connection or indirect connection by means of an intermediate medium; and may refer to communication between two elements, or interaction between two elements. A person of ordinary skills in the art could understand the specific meaning of the terms in the present disclosure according to specific situations.

In the present disclosure, unless otherwise explicitly specified and defined, the first feature being “on” or “under” the second feature may include the first feature and the second feature being in direct contact, or the first feature and the second feature being not in direct contact, but in contact with each other through another feature therebetween. Also, the first feature being “on”, “above” or “over” the second feature includes the first feature being right above or not right above the second feature, or merely means the level of the first feature being higher than that of the second feature. The first feature being “under”, “below” or “beneath” the second feature includes the first feature being directly below or not directly below the second feature, or merely means the level of the first feature being lower than that of the second feature.

The graphite pot of the present disclosure and the manufacturing method thereof are described in detail above, and the principle and the implementation modes of the present disclosure are set forth herein with specific examples. The above descriptions of the embodiments are only used to help understand the core idea of the present disclosure; and for a person of ordinary skills in the art, based on the idea of the present disclosure, the present disclosure may have variations on the aspects of the specific implementation modes and the application scope. In conclusion, the contents in this description shall not be construed as limiting the present disclosure.

What is claimed is:

1. A graphite pot, comprising a pot body made of graphite, the pot body comprising an inner wall and an outer wall, and a hard carbon film attached to at least the inner wall.

2. The graphite pot according to claim 1, wherein a non-stick coating is attached to the surface of the hard carbon film.

3. The graphite pot according to claim 1, wherein a non-stick coating or a hard carbon film is attached to the outer wall.

4. The graphite pot according to claim 1, wherein the thickness of the hard carbon film ranges from 1.0 μm to 50 μm.

5. A graphite pot, comprising a pot body made of graphite, the pot body comprising an inner wall and an outer wall, and a covalent carbide film attached to at least the inner wall.

6. The graphite pot according to claim 5, wherein a non-stick coating is attached to the surface of the covalent carbide film.

7. The graphite pot according to claim 5, wherein a non-stick coating or a covalent carbide film is attached to the outer wall.

8. The graphite pot according to claim 5, wherein the thickness of the covalent carbide film ranges from 1.0 μm to 5.0 μm.

9. The graphite pot according to claim 5, wherein the covalent carbide film is a silicon carbide film, a boron carbide film or a titanium carbide film.

10. A method for manufacturing a graphite pot, comprising the steps of:
molding graphite into a pot body; and
subjecting the pot body to a coating treatment via chemical vapor deposition or to a coating treatment via physical vapor deposition to form a hard carbon film on a surface of the pot body.

11. The method for manufacturing a graphite pot according to claim 10, wherein the specific operations of the coating treatment via chemical vapor deposition are:
placing the baked pot body into a coating chamber, and closing and vacuumizing the coating chamber; and
controlling an air pressure P₁ in the coating chamber, a recovery pressure P₂, glow bar power P₃, an argon flow rate Q₁, a hydrogen flow rate Q₂ and a methane flow rate Q₃, base material temperature T₁ of the pot body and deposition time t₁, and performing coating of the pot body via chemical vapor deposition.

12. The method for manufacturing a graphite pot according to claim 11, wherein the air pressure P₁, the recovery pressure P₂, the glow bar power P₃, the argon flow rate Q₁, the hydrogen flow rate Q₂, the methane flow rate Q₃, the base material temperature T₁ of the pot body and the deposition time t₁ satisfy the following relations:
P₁ ranges from 0.5 kpa to 7 kpa, P₂ ranges from 50 kpa to 150 kpa, P₃ ranges from 2 kw to 20 kw, Q₁ ranges from 1 SLM to 10 SLM, Q₂ ranges from 0.5 SLM to 4.5 SLM, Q₃ ranges from 0.02 SLM to 0.6 SLM, T₁ ranges from 850° C. to 930° C., and t₁ ranges from 1 hour to 12 hours.

13. The method for manufacturing a graphite pot according to claim 10, wherein the specific operations of the coating treatment via physical vapor deposition are:
placing the baked pot body into a coating chamber, and closing and vacuumizing the coating chamber; and
controlling a background pressure P₄ in the coating chamber, a film-forming pressure P₅, a sputtering power P₆, a bias voltage Vbias, an argon flow rate Q₄, a methane or acetylene flow rate Q₅, base material temperature T₂ of the pot body and deposition time t₂, and performing coating of the pot body via physical vapor deposition.

14. The method for manufacturing a graphite pot according to claim 13, wherein the background pressure P₄, the film-forming pressure P₅, the sputtering power P₆, the bias voltage Vbias, the argon flow rate Q₄, and the methane or acetylene flow rate Q₅, the base material temperature T₂ of the pot body and the deposition time t₂ satisfy the following relations:
P₄ ranges from 0.5×10⁻² Pa to 0.5×10⁻³ Pa, P₅ ranges from 2.0×10⁻² Pa to 8.0×10⁻¹ Pa, P₆ ranges from 10 kw to 20 kw, Vbias ranges from 100V to 300V, Q₄ ranges from 0.2 SLM to 0.7 SLM, Q₅ ranges from 0.10 SLM to 2.0 SLM, T₂ ranges from 130° C. to 200° C., and t₂ ranges from 3 hours to 5 hours.

15. The method for manufacturing a graphite pot according to claim 10, further comprising the steps of:
subjecting the pot body to a coating treatment via physical vapor deposition to form a covalent carbide film on a surface of the pot body.

16. The method for manufacturing a graphite pot according to claim 15, wherein the coating treatment via physical vapor deposition is sputtering.

17. The method for manufacturing a graphite pot according to claim 16, wherein the specific operations of the sputtering are:
placing the baked pot body into a coating chamber, and closing and vacuumizing the coating chamber; and
controlling a deposition pressure P₁ in the coating chamber, a sputtering target material, a sputtering power P₂, an argon flow rate Q₁, and an acetylene flow rate Q₂, base material temperature T₁ and deposition time t₁, and performing sputtering of the pot body.

18. The method for manufacturing a graphite pot according to claim 17, wherein the deposition pressure P₁, the sputtering target material, the sputtering power P₂, the argon flow rate Q₁, the acetylene flow rate Q₂, the base material temperature T₁ and the deposition time t₁ satisfy the following relations:
P₁ ranges from 0.5×10⁻¹ Pa to 5.0×10⁻¹ Pa, the sputtering target material is silicon, boron or titanium, P₂ ranges from 5 kw to 20 kw, Q₁ ranges from 0.05 SLM to 3.0 SLM, Q₂ ranges from 0.04 SLM to 0.10 SLM, T₁ ranges from 110° C. to 130° C., and t₁ ranges from 1.5 hours to 4 hours.
